(19) United States
(12) Patent Application Publication
(10) Pub. No.: US 2022/0163832 A1
(43) Pub. Date: May 26, 2022

(54) INFORMATION INPUT AND DISPLAY DEVICE FOR USE UNDERWATER (EMBODIMENTS)

(71) Applicant: DUSOL LIMITED LIABILITY COMPANY, Moscow (RU)

(72) Inventor: Evgeny Borisovich Alexandrov, Moscow (RU)

(21) Appl. No.: 17/434,799

(22) PCT Filed: Mar. 3, 2020
(86) PCT No.: PCT/RU2020/050034

§ 371 Date: Aug. 30, 2021

(30) Foreign Application Priority Data
Mar. 28, 2019 (RU) 2019109051
Mar. 28, 2019 (RU) 2019109052
Aug. 30, 2019 (RU) 2019127921

(51) Int. Cl. G02F 1/1333; G02F 1/1339; G02F 1/167; G02F 1/1679; G02F 1/16753; G06F 3/041

(52) U.S. Cl. CPC G02F 1/13338; G02F 1/1339; G02F 1/167; G06F 2203/04102; G02F 1/16753; G02F 1/133308; G06F 3/0412; G02F 1/1679

(57) ABSTRACT

There is provided an information input and display device for use underwater, comprising a housing, a touch screen accommodated in the housing, electronic components to provide operation of the screen, wherein the touch screen has an upper flexible layer sensitive to a mechanical stimulus sufficient to depress the flexible layer at the stimulus location, and the housing has a window for access to the upper flexible layer and is sealed with a dielectric sealant such that at least a portion of the upper flexible layer remains uncovered with the dielectric sealant to allow contact with water.

### BACKGROUND OF THE INVENTION

The invention relates generally to devices for input and display of information. More specifically, the invention is aimed to provide a device for input and display of information underwater and may be used to make various records of texts, drawings, pictures of visually percepted information underwater.

In underwater activities, divers often need to make records (e.g. a diving profile, parameters and conditions of the dive), drawings (e.g. a dive location diagram), and exchange information (messages) with other divers.

For these purposes, the use is generally made of plastic tablets (slates) which have a writing surface to make notes and draw with a pencil, and such devices are commonly referred to as dive slates. They can have a plastic writing surface and a graphite pencil.

However, erasure of recorded information may take a lot of time, since it is done by repeated exposure of the slate writing surface to friction. Furthermore, the repeated use inevitably leaves marks on the writing surface, which lowers the quality of further records. Also, the pencil shaft may break, making impossible further recording of information underwater, and impair the dive performance and safety.

U.S. Pat. No. 7,264,477 (publ. 2007) discloses a device with a rolled plastic sheet which forms changing parts in a screen window. The device is completely mechanical and has no tablet computer elements with all that implies.

Drivers can also use magnetic tablets (slates), e.g. https://scubares.com/innovative-scuba-concepts-quest-underwater-slate-is-magnetic-erasable/. However, magnetic tablets are inconvenient because of their size, weight, and they have very large and non-adjustable linewidth (regardless of pressure on the stylus). In many cases upon repeated use of the tablet, residues of magnetic powder form on the screen, lowering the reproduced information quality. Furthermore, loss of the special stylus/pencil prevents further use of the device. At a dive to a depth of more than 10 meters, the quality of records on the device substantially degrades and lines become almost invisible.

U.S. Pat. No. 5,956,291 (publ. 1999) discloses a mobile electronic apparatus for underwater writing, comprising a watertight body, an integrated dive computer, a digital camera, a vessel locator, an audible tones generator, a display, an electromagnetic pen digitizer, a communication subsystem to communicate information to other devices. The pen digitizer is connected to the apparatus through a connector which plugs into a receptacle. Instead of entering information by pressure on the writing surface of the display, the information input is made by the electromagnetic pen digitizer followed by processing the digital signal and converting it into images displayed on the screen.

A disadvantage of this apparatus is an elaborated manufacturing process, including assembly of a great number of components, high power consumption due to the use of highlighted screen, microprocessors and electromagnetic pen digitizer, provision of an external power supply on the diver's weight belt, connection of the electromagnetic pen digitizer to the apparatus body. Moreover, damage or loss of the pen makes input of information impossible. In addition, the use of metal elements, supplementary modules, external power supply and glass screen substantially increases the apparatus weight and cost.

Another conventional device, disclosed in published patent application US 2016/0313769, comprises an LCD display panel accommodated inside a sealing structure. The display panel and electronic components are completely protected by the sealing structure including a transparent portion (window) for visual access to information on the display panel. The technical solution is conceptually directed at improved water isolation of all internal components of the device and even recommends double or multiple sealing to enhance the protection of components, including the display panel inside. According to the specification, information is entered through an audio input. No other ways of entering information are disclosed. The disadvantage of this device is that the additional layer of the sealing structure (window) decreases contrast of the display panel, and that it is impossible to enter information by direct action on the display panel with a stylus.

Most closely related to the present invention is the disclosure of patent application US 2005/0110765 (publ. 2005), which teaches the device having similar purpose and operation principle, comprising: a watertight main body, a dive computer, an LCD screen having a writing surface over the entire screen area or incorporated as portion of the display screen, and an electronic component for automatically equalizing the gap between a top sheet of the writing surface and the glass screen responsive to pressure. The gap between the top sheet of the writing surface and the screen is not more than 0.005 inches (0.013 cm). A disadvantage of the apparatus is the need to use an electronic component for equalizing the ambient water pressure applied to the glass screen when a diver descends underwater, and a pressure sensor; this significantly complicates the manufacturing process and increases the final cost of the apparatus. In addition, the provision of the integrated dive computer in the apparatus is redundant in many cases, since most divers use separate individual dive computers, and the computer in the apparatus significantly increases its weight and makes the use of the apparatus inconvenient, particularly for underwater records. It is also quite obvious that the plurality of additional components inevitably increases power consumption.

US 2005/0110765 (specification, paragraph 0022) teaches: “Main body 14 is made of a durable material that can withstand harsh environments, such as an underwater environment. In order for the main body 14 to withstand an underwater environment and the pressure associated with such an environment, main body 14 has minimal air pockets contained within the main body. For instance, with the exception of the gap 36, the main body 14 may be filled with a layer of silicon-based gel or some other inert material to fill any air pockets”.

However, gel is unable to function as a stable sealant due to the fact that when the tablet changes its position, the gel, by its consistency and properties, can flow from one air pocket into another and split into parts. Gel does not solidify and remains relatively liquid, i.e. it can leak out at any damage to the body. Also, at possible shaking of the apparatus in operation, its internal parts may shift and be damaged under the pressure of shifting gel. Furthermore, the main task of gel is to displace air from air pockets of the apparatus, rather than to seal electronic components from water or condensate formed when temperature is changing during dive.

Therefore, there is a need for a simple and reliable information input and display device for use underwater, which doesn't require equalizing the pressure applied on the screen writing surface as the dive depth is changing, can avoid additional electronic components, including a special electronic stylus, and ensure low power consumption.

There is also a need for an information input and display device for use underwater, comprising a writing screen that allows information input both with and without stylus, has a large number of erase cycles, and can adjust linewidth responsive to pressing force (e.g. by stylus) on the screen.

### SUMMARY OF THE INVENTION

It is an object of the invention to provide a simple information input and display device for use underwater, which, due to the use of a touch screen enabling input of information underwater by direct action on the screen, eliminates the necessity to equalize pressure upon the screen writing surface, and avoids the need for additional electronic units, including a special electronic stylus. Furthermore, an object of the invention is to enable erasing information from the screen by a hall sensor or a reed switch instead of a control button.

Advantages offered by the invention include successful use of conventional touch screens for input and display of information underwater owing to sealing the interior of the touch screen from water and air and simultaneously sealing electrical components that ensure operation of the screen.

When the device comprises a housing, the aforementioned advantages are ensured by sealing free cavities inside the housing from water and air. Free cavities inside the housing are filled with a dielectric sealant so that in the process of filling, air is displaced from the housing and electrical components (including electronic printed circuit board and battery terminals) are simultaneously sealed. Therefore, the device is protected from external impacts and from condensation on electrical components as the temperature is changing with depth during the dive.

According to a first aspect of the invention, the object is attained by an information input and display device for use underwater, comprising a touch screen having an upper flexible layer sensitive to a mechanical stimulus, and electronic components to provide operation of the screen, wherein the screen and the electronic components are sealed from water by a dielectric sealant, while allowing contact of at least a portion of the upper layer of the screen with water.

According to a second aspect of the invention, the object is achieved by an information input and display device for use underwater, comprising a water-tight housing, a touch screen having an upper flexible layer sensitive to a mechanical stimulus and accommodated in the housing, electronic components to provide operation of the screen, wherein the electronic components are sealed from water by a dielectric sealant, while allowing contact of at least a portion of the upper layer of the screen with water.

According to one more aspect of the invention the object is attained by an information input and display device for use underwater, comprising a housing, a touch screen accommodated in the housing, electronic components to provide operation of the screen, wherein the touch screen comprises an upper flexible layer sensitive to a mechanical stimulus that is sufficient to depress the flexible layer at the stimulus location, wherein the housing has a window for access to the upper flexible layer of the touch screen and is sealed with the dielectric sealant so that at least a portion of the outer surface of the upper flexible layer of the screen in the window remains uncovered with the dielectric sealant to allow contact with water.

The touch screen is preferably a low-energy bistable cholesteric liquid crystal screen or electronic paper screen, both having low energy consumption level.

The dielectric sealant is preferably selected from compounds having the ability to change from initial liquid or viscous flow state to rubbery or solid state after mixing components. Various types of potting compounds can be used to isolate electronic components of the device from condensation and water.

It is preferable to select substances having a viscosity such that, in viscous flow state, they can displace air from air cavities inside the housing.

One more advantage of the invention is the ability to erase displayed information from the screen using a hall sensor or reed switch, which is activated by a magnet arranged e.g. directly in the stylus.

The above objects are attained by an information input and display device for use underwater, comprising a touch screen, wherein the screen and electronic components comprising a hall sensor or reed switch are isolated from water, while allowing contact of at least a portion of the upper layer of the screen with water, and the erase function is activated by effect of the magnet on the hall sensor or reed switch.

### BRIEF DESCRIPTION OF THE DRAWINGS

Understanding that the accompanying drawings depict only typical embodiments of the invention and are, therefore, not to be considered to be limiting of the scope of protection, the invention will be described and explained with specificity and detail in reference to the accompanying drawings, in which:

FIG. 1 is a general view, on the screen side, of an information input and display device for use underwater according to the invention in assembled condition;

FIG. 2 is the interior of housing of the device according to the invention, not filled with a dielectric sealant;

FIG. 3 is the interior of housing of the device according to the invention, filled with a dielectric sealant;

FIG. 4 is a back view of the device, including back side of the housing;

FIG. 5 is a portion of a stylus containing a magnet.

### DETAILED DESCRIPTION OF THE INVENTION

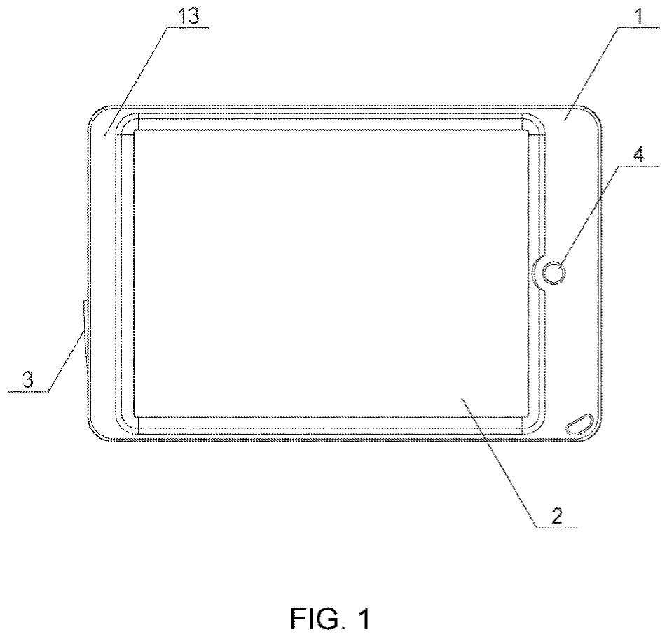

FIG. 1 depicts a general view, on the screen side, of an information input and display device for use underwater, in assembled condition. The drawing shows a housing 1 with a front portion 13 of the housing 1.

As will be an apparent to those skilled in the art, the device according to the invention can be, in principle, used without a housing 1. The housing is a preferable, but not essential element of the device, intended only for protection against external impacts, for aesthetic purposes, and for comfort of use. The main prerequisite for operability of the device is sealing the screen and other elements of the device from penetration of air and water, rather than provision of a housing, as will be shown below.

In this embodiment, a screen 2 is mounted in a housing 1.

As stated before, the main problem with prior art devices is the inability of underwater use of touch screens with the upper layer (writing surface) in direct contact with water.

Numerous attempts have been made to find suitable devices with touch screens, which would remain functional at direct water contact with the upper layer (writing surface) of the screen.

It was quite unexpectedly discovered that touch screens, e.g. based on cholesteric liquid crystals, can remain functional when used underwater at a depth of at least 40 meters, although they have never been earlier used underwater in direct contact with water.

The prerequisite for using such devices under water is the provision of their complete water and air tightness for protecting internal elements of the device from effects of ambient pressure and water.

Air can get into the interior of the device e.g. in the process of its assembly.

If air or water gets inside the device, it will be substantially impossible to enter information by acting upon the screen, e.g. by a stylus, under water due to the presence of air-filled cavities and/or water penetration, including the space between the screen boards. In addition to leaks leading to closure of electrical contacts in the device and failure of the screen, air pressure in the cavities increases with depth and causes, inter alia, deformation of the screen and often the housing as well.

It was found advantageous to use underwater devices with cholesteric liquid crystal screens. Unique properties of cholesteric screens permit using them underwater with the upper layer (writing surface) in direct contact with water.

An advantage of using such screens is that cholesteric screens spend energy only on changing the image, while a static image can displayed for a long time even when power is turned off. In addition to the extremely low power consumption, advantages of cholesteric liquid crystals include the ability to change their state under external electric field. In addition, liquid crystal screens showed good performance when immersed in liquid medium.

Drawing devices based on cholesteric liquid crystals are known in principle, e.g. https://myboogieboard.com/products/. These devices allow input of information by acting upon the screen with a stylus or another hard object, including a fingernail. However, no attempts have been made before to use such devices under water, especially with the screen in direct contact with water.

The device comprises a housing, an LCD screen and electronic components, including an electronic printed circuit board and a battery electrically connected to the screen, and a stylus. The device is operated by the unique property of cholesteric liquid crystals, which flow at different speeds depending on the direction of pressure (anisotropic flow). When a thin film with cholesteric liquid crystals is placed between two special plastic sheets, the anisotropic flow forces molecules to self arrange so that to reflect light at the locations where the stylus touches the plastic sheet and depresses it. Liquid crystals are surrounded by polymer columns that control the flow, thereby providing superior sharpness of lines. Recorded image is retained until it is erased by pressing a button (or by effect of a magnet upon a hall sensor or reed switch, which can be used instead of the button), which activates generation of electric field (electric pulse). At electronic erasure, a burst of electric field rearranges molecules so that they become less reflective.

In terms of quality, cholesteric liquid crystal screens are closer to e-paper screens, therefore, any type of said screens can be used underwater.

Conventional electronic paper device Sony DPT-RP1 (https://www.sony.com/electronics/digital-paper-systems/t/digital-paper-notepad), which permits input of information by acting upon a touch screen with a stylus, has also proven to be applicable in the present invention. In contrast to traditional liquid crystal screens using a matrix gap to generate an image, e-paper generates an image in reflected light like an ordinary paper and can store images of text and graphics for a quite long time without consuming electrical power and spending it only on changing the image.

Therefore, it has been found that any device comprising a touch screen with an upper flexible layer sensitive to a mechanical stimulus can be used underwater for input and display of information, particularly, devices with cholesteric liquid crystal touch screens, e-paper devices, and other devices with similar principles of operation. As will be apparent to those skilled in the art, other similar devices can also be successfully used without departing from the idea, principle and scope of the present invention. When choosing the appropriate device, the primary idea is to observe the principle that the screen, which is directly in contact with water, must have a layer sensitive to a mechanical stimulus, and this layer must have flexible properties.

FIG. 1 shows a control button 4 used to actuate the function of erasing information recorded with a stylus 3 from the screen. The stylus 3 may be any solid object able to transfer pressing force to the screen without damaging it, and the control button 4 can be replaced with a reed switch or a hall sensor to enable information erasure by applying a magnet to the housing where the hall sensor or reed switch is located. In this case, the stylus 3 can be provided with a magnet to activate the erase function through interaction between the reed switch or the hall sensor and the magnet.

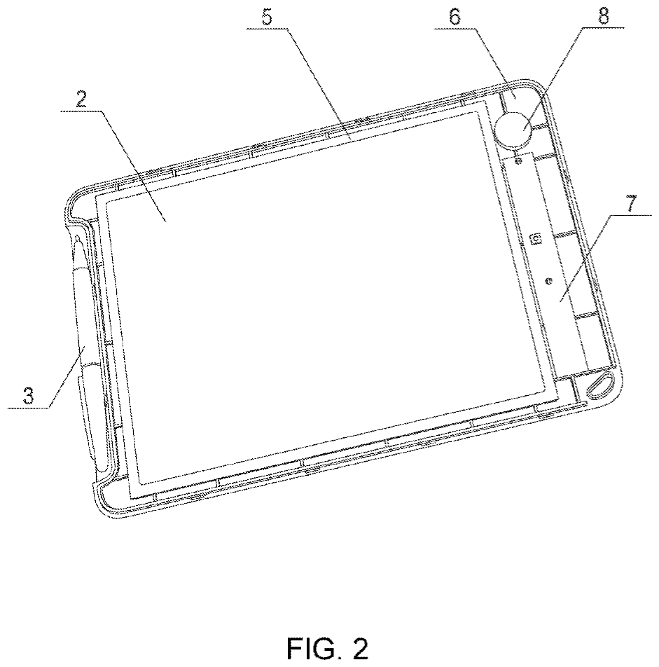

FIG. 2 shows the interior of the housing 1, not yet sealed from water, in which an electronic printed circuit board 7 with electronic components and a battery 8 are mounted. As seen in FIG. 2, the screen 2 accommodated in the housing 1 adheres tightly to a rigid substrate 5 or an inner part 6 of the back cover 11 of the housing 1. The tightness is caused by the necessity to avoid air and condensation from entering the interior of the screen after it has been sealed with a dielectric sealant. Furthermore, the screen per se adheres tightly to a special rigid substrate 5 or directly to the back wall (inner part 6) of the housing 1, since it is highly undesirable for the dielectric sealant to get under the screen. Therefore, the dielectric sealant is filled only on the edges. Dielectric sealant filled under the screen gives rise to appearance of irregularities thereon, which can damage the screen or interfere with its normal operation.

The housing 1 can have a design at which the screen tightly adheres, over its edges, against the upper (front) portion of the housing from the inside and is fixed, for example, by an adhesive bond or ultrasonic welding or double-sided moisture-resistant tape.

On the side of terminals, the screen is sealed simultaneously with sealing the electronic printed circuit board with electronic components thereon.

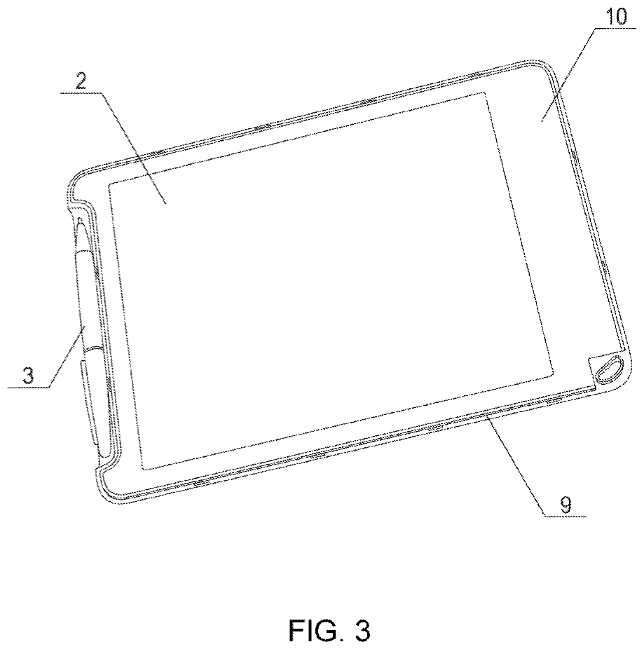

FIG. 3 shows the interior of the housing 1, which is filled with a dielectric sealant 10.

Dielectric sealant 10 must have the ability to exclude its movement once it has solidified and to eliminate direct effect of ambient pressure variation with depth on electronic components of the device and internal elements of the screen.

It is desirable that the dielectric sealant was able to change, in a while after mixing its components, from initial viscous-flow state to final rubbery or solid state. This is because during the change from viscous flow state to rubbery or solid one, the dielectric sealant expels air from free cavities of the device, and fills free cavities in the closed housing between the device components. Concurrently, the device screen retains its functionality underwater when exposed to ambient pressure and force as the external ambient pressure applied to the device and its elements changes with depth. This effect is provided, inter alia, by the absence of free air cavities in the device housing, including directly under the screen, which is arranged on and adhered to (as seen in FIG. 2) the rigid substrate or the back wall of the housing 1.

Unlike gel used in patent publication US 2005/0110765 to expel air from air pockets, the dielectric sealant solidifies after being placed in the device housing and does not leak out, reliably holding in place and protecting all internal components. Furthermore, unlike gel, the proposed dielectric sealant is rubbery or solid in working condition, which is very important for using under the exposure to ambient pressure as the depth is increasing, since in the solidified state it can reduce vibration, shock and other negative effects on the device. In addition, the gel, when flowing, can flow under the screen or between the screen boards, which is not the case of the rubbery or solid dielectric sealant. If gel is filled insufficiently, it will flow (squeeze out) from one end of the housing to the other. With rubbery or solid dielectric sealant, this is not possible. Therefore, gel used in patent publication US 2005/0110765 is substantially inapplicable for use in the inventive structure.

For example, as the rubbery dielectric sealant 10 having the ability to change from viscous flow state to rubbery one, a heat-conductive potting silicone dielectric sealant can be used, which is capable of sealing both in open and in closed volume. In Russia, such sealants are produced, for example, under SUREL-SL-KST trademark (http://www.surel.ru/silicone/70/), the heat-conductive potting silicone dielectric sealant comprising a two-component system able to change from viscous flow state to elastic state after mixing components A and B, where component A is a filled organosilicon polymer, and component B is a cold curing catalyst.

In addition to the above properties, the used elastic dielectric substance exhibits:
moderate damping and shock-absorbing properties;
sufficient elasticity;
high dielectric properties;
resistance to high and low temperatures.

As will be apparent to those skilled in the art, other similar materials with similar properties can be used as the dielectric sealant. For example, Silagerm 2206 (1/1) compound, Silagerm 2206 compound, Viksint PK-68, Viksint K-68, KPTD-1, Dow Corning Sylgard 184, Dow Corning Sylgard 182 compound can be used. It is also possible to use epoxy and other potting compounds going finally into solid state, e.g. Etal-1472, Etal-1471 and other similar compounds.

Electronic printed circuit board 7 with electronic components, battery terminals, screen terminals, and screen edges on the ends along the perimeter must be immersed into the dielectric sealant 10 and thus isolated from environmental influences and force effects when the ambient pressure on the device changes with depth, and from shock and vibration. Dielectric sealant 10 is poured into the housing 1 so that it does not get directly under the screen, but fills the space inside the housing along the perimeter and seals the screen along the edges. In addition, as already mentioned above, the screen per se adheres tightly to the rigid substrate 5 or directly to the back wall 6 of the housing 1.

Mating edges 9 are arranged over the perimeter of the housing 1.

Whether the device comprises a housing or not, the prerequisite for its operability is that the interior of the screen and electronic components are sufficiently isolated from penetration of air and water, and thereby isolated from environmental influences and force effects as the ambient pressure upon the device changes with depth.

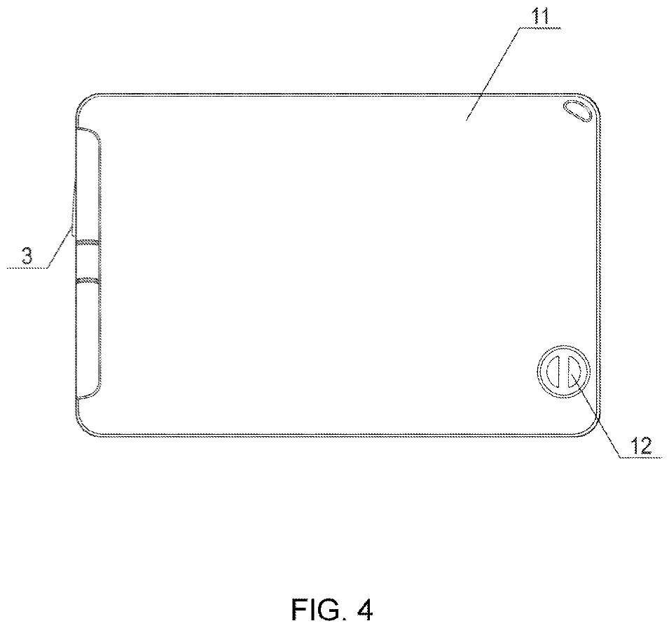

FIG. 4 shows a back view of the device, including a back cover 11 of the housing 1, a stylus 3 and a battery compartment cover 12 containing at least one o-ring (not shown).

Upon mounting the screen 2 on the front cover 13 of the housing 1 of the information input and display device and placing all the principal internal elements, including the electronic printed circuit board 7 and the battery 8, a dielectric sealant is poured over the entire plane of the open housing 1 with the mounted screen 2 to fill free air cavities. Then, the back cover 11 of the housing 1 is closed and secured by ultrasonic welding or adhesive bonding along the entire perimeter. As the result, the back cover 11 of the housing 1 provides tight contact with the rear portion of the screen 2 so that there is no air gap between the back cover 11 of the housing 1 and the screen 2. The rear portion of the screen 2 can also be pressed by a rigid substrate 5 (see FIG. 2) arranged between the rear portion of the screen 2 and the back cover 11 of the housing 1.

To replace the battery 8 in the housing 1, a special compartment (not shown) is provided with a cover 12 containing at least one o-ring, which is opened to replace the battery 8, and then the back cover 11 of the housing 1 is tightly closed.

The battery can be substituted, for example, for a rechargeable battery. In this case, the device is further provided with a sealed charging port or a wireless charging module.

The device can further comprise a module for storing the entered and displayed information and a module for transmitting information to other devices.

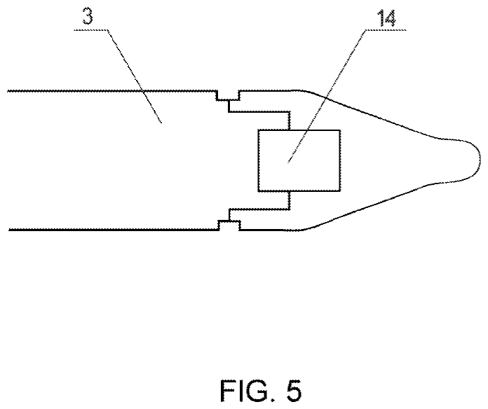

FIG. 5 shows a portion of a stylus 3 containing a magnet 14. When the stylus is brought to a special place for applying the magnet 14, the function of erasing from the screen 2 is actuated. This embodiment enables erasure of information from the screen without additional manipulations.

The information input and display device was tested in operation underwater at a depth of 40 meters at the water temperature of +28 degrees. Under these test conditions, the device was fully functional throughout the entire test cycle consisting of ten dives, each for 45-60 minutes.

The inventive information input and display device for use underwater is light in weight, easy to manufacture and convenient for making notes, records and drawings underwater, and consume low power.

1-6. (canceled)

7. An information input and display device for use underwater, comprising a touch screen based on cholesteric liquid crystals or electronic paper and having an upper flexible layer sensitive to a mechanical stimulus, and electronic components to provide operation of the screen, wherein the screen, with the exception of at least a portion of its upper layer, and the electronic components are isolated from water by a dielectric sealant.

8. The device according to claim 7, wherein the dielectric sealant comprises a composition able to change from initial liquid or viscous flow state to rubbery or solid state after mixing its components.

9. The device according to claim 8, further comprising a housing with a cavity to accommodate the touch screen and the electronic components, wherein said housing has a window for access to the upper flexible layer of the screen and is sealed with the dielectric sealant so that at least a portion of outer surface of the upper flexible layer of the screen in the window remains uncovered with the dielectric sealant to allow contact with water.

10. The device according to claim 9, wherein the rubbery or solid dielectric sealant has a viscosity at which, in viscous flow state, the sealant is able to displace air from air cavities inside the housing.

11. The device according to claim 9, further comprising a stylus mounted on the housing to input information by applying mechanical stimulus upon the upper layer of the screen, and means for erasing information displayed on the screen.

12. The device according to claim 10, further comprising a stylus mounted on the housing to input information by applying mechanical stimulus upon the upper layer of the screen, and means for erasing information displayed on the screen.

13. The device according to claim 11, wherein said means for erasing information displayed on the screen comprises a reed switch or a hall sensor mounted in the cavity of the housing, and a magnet mounted in the stylus.

14. The device according to claim 12, wherein said means for erasing information displayed on the screen comprises a reed switch or a hall sensor mounted in the cavity of the housing, and a magnet mounted in the stylus.
